(19) United States
(12) Patent Application Publication
(10) Pub. No.: US 2007/0063880 A1
(43) Pub. Date: Mar. 22, 2007

(54) Highspeed serial transmission system and a method for reducing jitter in data transfer on such a system

(76) Inventors: Joerg Goller, Zweikirchen (DE); Harald Sandner, Marzling (DE)

Correspondence Address: TEXAS INSTRUMENTS INCORPORATED, P O BOX 655474, M/S 3999, DALLAS, TX, 75265, US

(21) Appl. No.: 11/384,600

(22) Filed: Mar. 20, 2006

(30) Foreign Application Priority Data
Mar. 23, 2005 (DE) 10 2005 013481.5

(51) Int. Cl. H03M 9/00

(52) U.S. Cl. 341/100

(57) ABSTRACT

In a high-speed serial transmission system (10) comprising a transmitter (12), a transmission line (14) and a receiver (16), the transmitter (12) includes a bit-stream generator (18) for generating a predetermined pseudo random bit sequence (PRBS), and a controllable phase distortion circuit (20) having an input (24) connected to the bit-stream generator (18) and a signal output (26) connected to the transmission line (14). The receiver (16) includes a sampling circuit (30) with a signal input (36) connected to the transmission line (14), a sampling clock input (38) and a data output (40), a clock recovery circuit (32) with a phase-locked loop circuit (42) and a controllable phase interpolator (44) that has signal inputs (45) connected to signal outputs of the phase-locked loop circuit (42) and an output (48) connected to the sampling clock input (38) of the sampling circuit (30), and a bit-stream verification circuit (32) with an input (50) connected to the data output (40) of the sampling circuit (30) and an output (52) that controls the controllable phase interpolator. An output (54) of the bit-stream verification circuit (34) controls the controllable phase distortion circuit (20) in the transmitter (12) in response to a bit error rate (BER) detected in the bit-stream received form the data output (40) of the sampling circuit (30) by comparison with the predetermined pseudo random bit sequence (PRBS).

### CROSS REFERENCE TO RELATED APPLICATIONS

This application claims priority under 35 USC § 119 of German Application Serial No. 10 2005 013481.5, filed Mar. 23, 2005.

### FIELD OF THE INVENTION

The invention relates to a high-speed serial transmission system comprising a transmitter, a transmission line and a receiver. The invention further relates to a method for reducing jitter in data transfer on such a transmission system.

### BACKGROUND OF THE INVENTION

Due to the bandwidth limiting behavior of transmission lines, inter symbol interference effects (ISI) add data dependent jitter components to the overall jitter. The ISI effect shortens a bit in that the leading edge is delayed and the trailing edge is earlier than it should be in an ideal bit. ISI effects always happen when there is no transmission for a long time followed by switching to the opposite state and back within one bit time. For instance, in a bit sequence like . . . 000010, the single “1” is shortened by capacitive loading effects.

An adequate visualization for showing the effects of jitter is an eye diagram. The eye diagram illustrates multiple samples of the signal over one period. The eye opening is defined as the area in the diagram where the signal can securely be sampled in the receiver. Usually the eye opening is expressed in a fraction of a unit interval UI. The unit interval UI is the time period equivalent to one bit time in a serial data stream. FIG. 2 shows an eye diagram of a differential signal received at the end of a differential transmission line. Due to the jitter in the signal, the eye opening is reduced or “closed”. As a result, the length of the transmission line is limited or a better quality of cable and connections is required to reduce resistive and capacitive loading.

The intersignal interference effects can be compensated by phase distortion of the signal in the transmitter. However, the level of phase distortion depends on the parameters of the transmission line. If these parameters change with time or if the transmission line itself is replaced, the phase distortion which was initially set may not provide optimum performance any more.

### SUMMARY OF THE INVENTION

The invention provides a transmission system with persistently minimized jitter.

Specifically, a high-speed serial transmission system is provided, comprising a transmitter, a transmission line and a receiver. The transmitter includes a bit stream generator for generating a predetermined pseudo random bit sequence and a controllable phase distortion circuit having an input connected to the bit stream generator and a signal output connected to the transmission line. The receiver includes a sampling circuit with a signal input connected to the transmission line, a sampling clock input and a data output. The receiver further includes a clock recovery circuit with a phase locked loop circuit and controllable phase interpolator that has signal inputs connected to the signal outputs of the phase locked loop circuit and an output connected to the sampling clock input of the sampling circuit. Further, the receiver includes a bit stream verification circuit with an input connected to the data output of the sampling circuit and an output that controls the controllable phase interpolator. An output of the bit stream verification circuit controls a controllable phase distortion circuit in the transmitter in response to a bit error rate detected in the bit stream received from the data output of the sampling circuit by comparison with the predetermined pseudo random bit sequence. This transmission system can automatically adapt the phase distortion to the physical parameters of the transmission line and therefore provide optimum performance.

According to a second aspect, the invention provides a method for persistently reducing jitter in data transfer on a high-speed serial transmission system.

Specifically, a method for reducing jitter in data transfer on a high-speed serial transmission system is provided, which comprises the steps of having the clock recovery circuit locked in to an initial value for the phase of the sampling clock signal and then executing a test cycle. The test cycle comprises the steps of controlling the bit-stream generator to generate a pseudo random bit sequence, sending the pseudo random bit sequence via the transmission line from the transmitter to the receiver, detecting an error rate in the received pseudo random bit sequence with the bit-stream verification unit and controlling the phase interpolator to change the phase of the sampling clock signal by one step. The test cycle is sequentially repeated for a number of different phase angle values, and the effective eye opening for the data transmission arrangement is calculated with the bit-stream verification circuit from the detected error rates. Then, the bit-stream verification unit controls the phase distortion circuit to set up a configuration for minimum jitter according to the calculated effective eye opening. The method allows to set the phase distortion circuit into an optimum configuration for the parameters of the transmission line which are measured indirectly by detecting the error rates and calculating the eye opening. If the method is carried out for example in a reset sequence upon switching on of the transmission system, the configuration is always optimally adapted to the transmission line in use. This is especially advantageous if the transmission system includes plug-in connections as for example back planes of data switches.

A modified method according to the invention, comprises the steps of having the clock recovery circuit locked in to an initial value for the phase of the sampling clock signal, controlling the phase distortion circuit to set up a first configuration and executing a test cycle. The test cycle comprises the steps of controlling the bit-stream generator to generate a pseudo random bit sequence, sending the pseudo random bit sequence from the transmitter via the transmission line to the receiver, detecting an error rate in the received pseudo random bit sequence with the bit-stream verification unit and controlling the phase interpolator to change the phase of the sampling clock signal by one step. The test cycle is sequentially repeated for a number of different phase angle values. The effective eye opening for the setup configuration of the phase distortion circuit is calculated from the detected error rates and stored in the bit-stream verification unit. The steps are repeated for all possible configurations of the phase distortion circuit. Then, the calculated effective eye opening values are compared and the phase distortion circuit is controlled to set up the one configuration which established the maximum eye opening. With this method, the data transmission system can automatically adapt the phase distortion configuration to the parametrics of the transmission line. There is no need for having a list of predetermined configurations for different measured parameters.

### BRIEF DESCRIPTION OF THE DRAWINGS

Further advantages and features of the invention will become apparent from the following detailed description with reference to the appended drawings. In the drawings:

FIG. 1 shows a block diagram of a data transmission system according to the invention;

FIG. 2 shows an eye diagram of a transmitted signal bearing jitter; and

FIG. 3 shows a diagram illustrating the distribution of bit error rate over one unit interval UI.

### DETAILED DESCRIPTION OF THE DRAWINGS

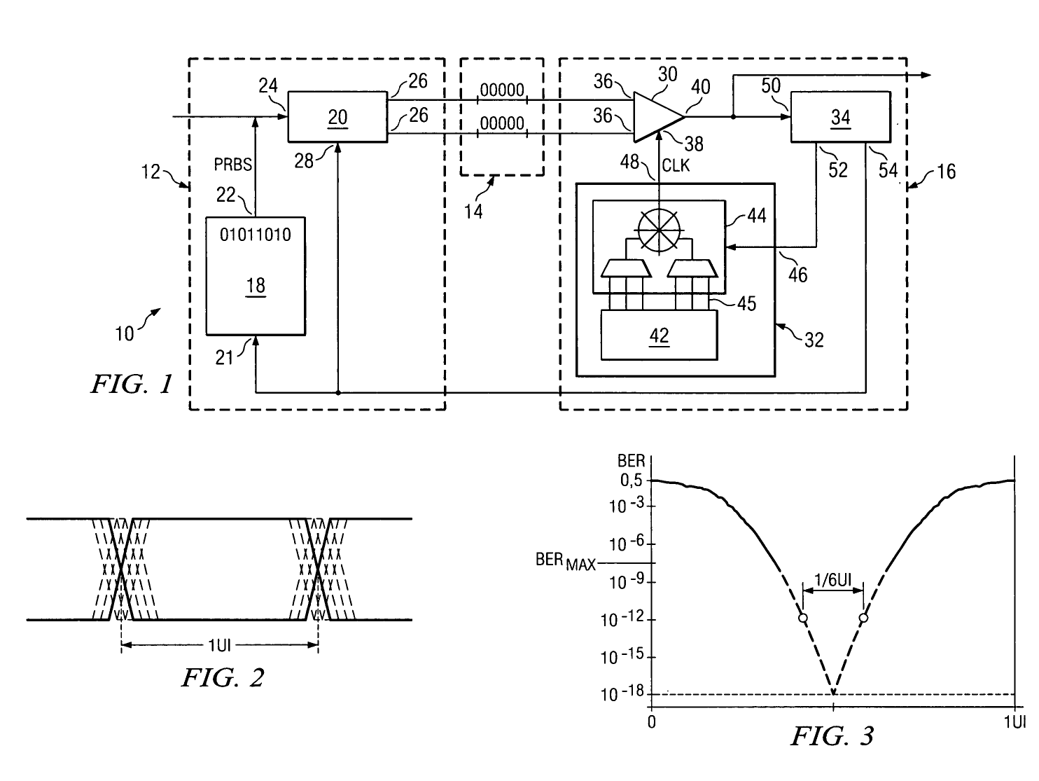

The high-speed serial transmission system 10 illustrated in FIG. 1 comprises a transmitter 12, a transmission line 14 and a receiver 16.

The transmitter 12 includes a bit stream generator 18 and a phase distortion circuit 20. The bit-stream generator 18 has a control input 21 and an output 22 and is configured to generate a predetermined pseudo random bit sequence (PRBS) and provide it at the output 22. Predetermined means that the sequence itself is reproducible.

The phase distortion circuit 20 has an input 24 which is connected to the bit stream generator an output 26 connected to the transmission line 14 and a control input 28. The phase distortion circuit 20 can receive serial data at its input 24 from the bit-stream generator 18 or from an external bit-stream source (not shown in FIG. 1) and drive the transmission line 14 with a differential signal containing the received data. Depending on the received data, the differential signal is distorted in phase by phase distortion circuit 20 to compensate for ISI effects. When, after a long sequence of bits in the same state, a short sequence or a single bit of the opposite state follows, the phase distortion circuit 20 advances the leading flank and retards the trailing flank of the single bit or the first bit of the short sequence. The sensitivity, i.e. the minimum length that defines a “long sequence” and the phase amplitude of the phase distortion can be controlled via the control input 28.

The receiver 16 includes a sampling circuit 30, a clock recovery circuit 32 and a bit stream verification circuit 34. The sampling circuit 30 has a differential signal input 36 connected to the transmission line 14, a sampling clock input 38 and a data output 40. In the sampling circuit 30, the differential signal from the transmission line 14 is received, sampled with a clock signal CLK received at the sampling clock input 38. By sampling the differential signal from the transmission line 14, the sampling circuit 30 ideally can recover the bit stream as it was received at the input 24 of the phase distortion circuit 20 and provide the reconstructed serial data at the data output 40.

The clock recovery circuit 32 comprises a phase locked loop (PLL) 42 and a phase interpolator 44. The PLL 42 receives an input signal derived from the differential signal of the transmission line 14 and provides a plurality of phase signals of the same frequency but equidistantly distributed in phase. The phase interpolator 44 has phase inputs 45 for receiving the plurality of phase signals from the PLL 42, a control input 46 and a clock signal output 48 connected to the sampling clock input 38 of the sampling circuit 30. The phase interpolator 44 provides the clock signal CLK for the sampling circuit 30 interpolated from a couple out of the plurality of phase signals, the phase of the clock signal CLK being controlled by a control signal at the input 46. Basic function of a clock recovery circuit with a PLL and a phase interpolator is known to the skilled man and needs not to be explained here in detail.

The bit stream verification circuit 34 has an input 50 connected to the data output 40 of the sampling circuit 30, a first control output 52 connected to the control input 46 of the clock recovery circuit 32 and a second control output 54 connected to the control input 21 of the bit-stream generator 18 and the control input 28 of the phase distortion circuit phase distortion circuit 20. The bit stream verification circuit 34 receives the reconstructed serial data from the sampling circuit 30. If the data stream is the PRBS generated in the bit-stream generator 18, the bit stream verification circuit 34 can detect an error rate in the data stream, since the PRBS is predetermined. The bit stream verification circuit 34 stores the detected error rate. The bit stream verification circuit 34 is able to control the clock signal CLK via the first control output 52. The bit stream verification circuit 34 is further able to control via the second control output 54 the phase amplitude and the sensitivity of the phase distortion circuit 20 in the transmitter 12 in response to an error rate detected in the PRBS. The state machine 54 can also control the bit stream generator 18 to generate a PRBS once or repeatedly.

In the following, a preferred method for operating the data transmission system 10 is described in detail.

It is assumed now that the phase locked loop 42 has locked in and the clock recovery circuit 32 is set to a first value for the phase of the sampling clock signal CLK by the bit stream verification circuit 34. According to the invention, a routine for measuring the effective eye opening of the transmission line 14 is now accomplished.

The routine includes a test cycle comprising the following steps: The bit stream verification circuit 34 controls the bit-stream generator 18 to generate a pseudo random bit sequence (PRBS). The PRBS is received by the phase distortion circuit 20 and transmitted via the transmission line 14 to the receiver 16. The differential signal containing the pseudo random bit sequence PRBS is received at the input 36 of the sampling circuit 30 and is sampled with the clock signal CLK received at the sampling clock input 38 from the clock recovery circuit 32. The PRBS data recovered by sampling is provided to the output data output.

The bit stream verification circuit 34 receives the PRBS data at the input 50. Since the PRBS is predetermined, the circuit 34 can detect any error in the data. Since the error count depends on the length of the bit sequence, a bit error rate is calculated and stored.

In order to determine the effective eye opening, the unit interval UI has to be scanned. This means that the bit error rate has to be detected for a number of phase values of the clock signal CLK.

This is executed in that the value for the phase of the clock signal CLK is incremented by the bit stream verification circuit 34 and then the test cycle described above is repeated by generating a PRBS in the bit-stream generator 18, sending it via transmission line 14 and sampling the differential signal by the sampling unit 30. The bit stream verification circuit 34 calculates and stores the bit error rate relating to the phase value. The cycle is repeated for subsequent phase values of the clock signal CLK.

The routine is finished when the complete unit interval UI has been scanned. The effective eye opening can then be calculated from the detected error rates stored in the bit stream verification circuit 34. FIG. 3 shows a diagram of the bit error rate BER distribution over one unit interval UI. The bit error rate can only be measured down to a minimum value BERₘᵢₙ since the PRBS is limited. Detecting lower error rates would require longer bit sequences and longer measuring time. However, the bit error rate in the middle of the diagram can be extrapolated from the measured values. For a given bit error rate BER the eye opening can be estimated from the diagram. In the example illustrated in FIG. 3, the eye opening at a BER of 10⁻¹² is ⅙ UI.

Since the calculated eye opening quantifies the total jitter, the bit stream verification circuit 34 is now able to set up the phase distortion circuit 20 with an appropriate predetermined configuration for phase distortion.

According to a further development of the invention, the bit stream verification circuit 34 does not set up a predetermined configuration for the phase distortion circuit 20 but sequentially repeats the routine with different configurations for the phase distortion circuit 20. The measured effective eye opening will vary with different configuration values, e.g. sensitivity or phase distortion amount. As a result, by comparing the stored eye opening values, an optimum configuration setting can be detected which is finally set up for operational data transmission.

The whole routine only requires a few seconds, so it can be carried out for example in a reset sequence when the device including the transmission system is switched on. Especially if the transmission line includes plug in connections, the configuration can always automatically be adapted to components which have been altered. In addition, aging effects can be compensated with the method according to the invention.

According to an alternative development of the invention, a modified test routine is implemented. Starting with a first value for the phase of the sampling clock, the cycle as described above is executed: Initiating generation of a PRBS by the bit-stream generator 18, sending it via the transmission line 14 to the sampling circuit 30, sampling the differential signal with the clock signal to provide the data to the data output 40 for the bit stream verification circuit 34. In contrast to the test cycle above, no error rate is calculated. If the value for the error count reaches a predetermined limit, the present phase value of the clock signal is marked as a first boundary of the effective eye opening. Then, starting from the first value again, the unit interval UI is scanned in the other direction until the error count again reaches the predetermined value and the corresponding phase value of the clock signal is marked as a second boundary of the effective eye opening. This method is much faster because not the whole unit interval UI has to be scanned and no error rates must be calculated.

In an embodiment, the predetermined limit for the error count value is one, which means that the unit interval UI is scanned in both directions until the first error occurs.

In the embodiment described, the phase distortion circuit is implemented as a phase distortion circuit. Of course, other implementations are applicable with the transmission system according to the invention, for example a phase distortion circuit which uses pre-emphasis.

The invention provides a transmission system with enhanced reliability of data transmission and recovery. For a given required bit error rate, longer transmission line, cheaper connectors, and cables may be used because of the self-adaption capability.

1. A high-speed serial transmission system (10) comprising a transmitter (12), a transmission line (14) and a receiver (16), wherein the transmitter (12) comprising:
a bit-stream generator (18) for generating a predetermined pseudo random bit sequence (PRBS); and
a controllable phase distortion circuit (20) having an input (24) connected to the bit-stream generator (18) and a signal output (26) connected to the transmission line (14);
the receiver (16) includes:
a sampling circuit (30) with a signal input (36) connected to the transmission line (14), a sampling clock input (38) and a data output (40);
a clock recovery circuit (32) with a phase-locked loop circuit (42) and a controllable phase interpolator (44) that has signal inputs (45) connected to signal outputs of the phase-locked loop circuit (42) and an output (48) connected to the sampling clock input (38) of the sampling circuit (30); and
a bit-stream verification circuit (32) with an input (50) connected to the data output (40) of the sampling circuit (30) and an output (52) that controls the controllable phase interpolator, and
wherein an output (54) of the bit-stream verification circuit (34) controls the controllable phase distortion circuit (20) in the transmitter (12) in response to a bit error rate (BER) detected in the bit-stream received form the data output (40) of the sampling circuit (30) by comparison with the predetermined pseudo random bit sequence (PRBS).

2. A method for reducing jitter in data transfer on a high-speed serial transmission system (10) according to claim 1, the method comprising the steps of:
having the clock recovery circuit (32) locked in to an initial value for the phase of a sampling clock signal (CLK);
executing a test cycle comprising the steps of:
1) controlling the bit-stream generator (18) to generate a pseudo random bit sequence (PRBS);
2) sending the pseudo random bit sequence (PRBS) from the transmitter (12) via the transmission line (14) to the receiver (16);
3) detecting an error rate (BER) in the received pseudo random bit sequence (PRBS) with the bit-stream verification unit (34); and
4) controlling the phase interpolator (44) to change the phase of the sampling clock signal (CLK) by one step;
sequentially repeating the test cycle for a number of different phase angle values;
calculating the effective eye opening for the data transmission arrangement (10) with the bit-stream verification circuit (34) from the detected error rates (BER); and
controlling the phase distortion circuit (20) by the bit-stream verification unit (34) to set up a configuration for minimum jitter according to the calculated effective eye opening.

3. The method of claim 2, wherein steps c) and d) include:
repeating the test cycle with the phase angle value being increased until a predetermined error rate occurs, the current phase angle value being marked as first boundary of an effective eye opening;
the phase angle being set back to the initial value again; and
repeating the test cycle with the phase angle value being decreased until a predetermined error rate occurs, the current phase angle value being marked as second boundary of an effective eye opening.

4. A method for reducing jitter in data transfer on a high-speed serial transmission system (10) according to claim 1, the method comprising the steps of:
having the clock recovery circuit (32) locked in to an initial value for the phase of the sampling clock signal (CLK);
controlling the phase distortion circuit (20) to set up a first configuration;
executing a test cycle comprising the steps of:
controlling the bit-stream generator (18) to generate a pseudo random bit sequence (PRBS);
sending the pseudo random bit sequence (PRBS) from the transmitter (12) via the transmission line (14) to the receiver (16);
detecting an error rate in the received pseudo random bit sequence (PRBS) with the bit-stream verification unit (34);
controlling the phase interpolator (44) to change the phase of the sampling clock signal (CLK) by one step;
sequentially repeating the test cycle for a number of different phase angle values;
calculating the effective eye opening for the setup configuration of the phase distortion circuit (20) from the detected error rates and storing the calculated value in the bit-stream verification unit (34);
sequentially repeating steps b) through e), for all possible configurations of the phase distortion circuit (20);
comparing the calculated effective eye opening values; and
controlling the phase distortion circuit (20) to set up the one configuration which established the maximum eye opening.
